(19) United States
(12) Patent Application Publication
(10) Pub. No.: US 2009/0224819 A1
(43) Pub. Date: Sep. 10, 2009

(54) CONSTANT CURRENT CIRCUIT, AND INVERTER AND OSCILLATION CIRCUIT USING SUCH CONSTANT CURRENT CIRCUIT

(75) Inventors: Yutaka Shibata, Kyoto (JP); Yoshiyuki Karasawa, Kyoto (JP); Ichiro Yokomizo, Kyoto (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 12/063,594

(22) PCT Filed: Aug. 8, 2006
(86) PCT No.: PCT/JP2006/315634

§ 371 Date: Feb. 12, 2008

(30) Foreign Application Priority Data
Aug. 17, 2005 (JP) 2005-236261

(51) Int. Cl. H01L 35/00; G05F 1/10; G05F 3/26

(52) U.S. Cl. 327/513; 327/538; 327/543

(57) ABSTRACT

A bias current source generates a constant current Iref by applying to a current-generating resistor a voltage proportional to a thermal voltage Vt. A first bipolar transistor and a second bipolar transistor are disposed in series on the path of the constant current which is generated by the bias current source. A third bipolar transistor forms a current mirror circuit with the second bipolar transistor. A fourth bipolar transistor has a base connected to the base of the first bipolar transistor and has an emitter connected to a temperature-compensating resistor. The constant current circuit outputs a sum of the collector currents of the third bipolar transistor and the fourth bipolar transistor.

### BACKGROUND OF THE INVENTION

1. Field of the Invention

The present invention relates to a constant current circuit.

2. Description of the Related Art

In many electronic circuits, a constant current circuit for generating a constant current that is constant even under fluctuation of temperature or power source voltage is used. A constant current circuit can be configured, for example, with a band gap reference circuit which generates a reference voltage that does not have a temperature dependency and a voltage current conversion circuit that converts the reference voltage into an electric current. For example, FIG. 4.50 of the non-patent document 1 describes a constant current circuit having such a configuration. According to this constant current circuit, one can obtain a constant current that is extremely stable and not dependent on temperature.

On the other hand, in an electronic device of battery-driving type such as a watch, it is desirable to reduce the consumption current of the circuit down to the limit in view of the life time of the battery. Namely, depending on an application in which the constant current circuit is used, there are cases in which one wishes to reduce the number of elements such as transistors as much as possible and to reduce the consumption current of the circuit. In such a case, it is general to use a bias current source which uses a thermal voltage such as described in FIG. 4.41 of the non-patent document 1.

[Non-Patent Document 1] “Analysis and Design of Analog Integrated Circuits for System LSI, upper volume, fourth edition of the original” edited by P. R. Gray and others, Baifukan, 10 Jul. 2003, pp. 356-381

However, a bias current source using a thermal voltage is inferior in terms of temperature characteristics to a constant current circuit using the above-described band gap reference circuit, though having a simple circuit configuration and having a small consumption current.

### SUMMARY OF THE INVENTION

The present invention has been made in view of the above circumstances, and one general purpose thereof is to provide a constant current circuit having a simple configuration and being excellent in temperature characteristics.

### Means for Solving the Problems

In order to solve the aforementioned problems, a constant current circuit according to one embodiment of the present invention includes a bias current source which generates a constant current by applying to a current-generating resistor a voltage proportional to a thermal voltage, and a temperature-compensating circuit which generates a temperature-compensating current by applying to a temperature-compensating resistor a voltage corresponding to a voltage between a base and an emitter of a bipolar transistor. This constant current circuit outputs a sum of the constant current generated by the bias current source and the temperature-compensating current generated by the temperature-compensating circuit.

The thermal voltage Vt and the voltage Vbe between the base and the emitter of the bipolar transistor have positive and negative temperature dependencies, respectively. Therefore, by sum of a value obtained by multiplying the constant current generated by the bias current source with predetermined coefficients and a value obtained by multiplying the temperature-compensating current generated by the temperature-compensating circuit with predetermined coefficients, the temperature dependency of the thermal voltage Vt and the temperature dependency of the voltage Vbe between the base and the emitter can be cancelled, whereby a constant current having a smaller temperature dependency can be generated.

The temperature-compensating circuit may include a first bipolar transistor and a second bipolar transistor which are disposed in series on a path of the constant current generated by the bias current source and whose base and collector are connected to each other; a third bipolar transistor which forms a current mirror circuit with the second bipolar transistor; and a fourth bipolar transistor having a base connected to the base of the first bipolar transistor, having a collector connected to the collector of the third bipolar transistor, and having an emitter connected to the temperature-compensating resistor. The constant current circuit may output a sum of the collector currents of the third bipolar transistor and the fourth bipolar transistor.

A voltage (Vbe1+Vbe2−Vbe3) obtained by subtracting the voltage Vbe3 between the base and the emitter of the third bipolar transistor from a sum (Vbe1+Vbe2) of the voltages between the base and the emitter of the first and second bipolar transistors is applied to the temperature-compensating resistor. Assuming that Vbe1=Vbe2=Vbe3=Vbe, the voltage Vbe is applied to the temperature-compensating resistor, and the current Ix which flows through the temperature-compensating resistor and the fourth bipolar transistor is given by Ix=Vbe/R1, where R1 is the resistor value of the temperature-compensating resistor. On the other hand, the constant current generated by the bias current source flows through the third bipolar transistor. According to this embodiment, by using the temperature characteristics of the current Ix which flows through the fourth bipolar transistor, the temperature characteristics of the constant current generated by the bias current source are cancelled, whereby a constant current having small temperature dependency can be generated.

The temperature-compensating circuit may include a first bipolar transistor and a second bipolar transistor which are disposed in series on a path of the constant current generated by the bias current source andwhose base and collector are connected to each other; a third bipolar transistor which forms a current mirror circuit with the secondbipolar transistor; a fourth bipolar transistor having a base connected to the base of the first bipolar transistor and having an emitter connected to the temperature-compensating resistor; and a fifth bipolar transistor having a base connected to the base of the first bipolar transistor andhavinganemitterconnectedtothecollectorof thethirdbipolar transistor. The constant current circuit may output a sum of the collector currents of the fifth bipolar transistor and the fourth bipolar transistor.

According to this embodiment, by disposing a fifth bipolar transistor in addition to the above-described temperature-compensating circuit, the current flowing through the third and fifth bipolar transistors can be approximated to the constant current generated by the bias current source.

The bias current source may include a sixth bipolar transistor whose base and collector are connected to each other; a seventh bipolar transistor having a base connected to the base of the sixth bipolar transistor and having an emitter connected to a fixed potential via a current-generating resistor; and a current mirror load connected to the collectors of the sixth and seventh bipolar transistors. The constant current circuit may output a current proportional to a current flowing through the current mirror load.

Since a voltage proportional to the thermal voltage Vt is applied to the current-generating resistor, a current proportional to the thermal voltage is generated by this bias current source.

The above-described constant current circuit may be integrated on one semiconductor substrate. Here, “integration” includes a case in which all of the constituent elements of the circuit are formed on the semiconductor substrate and a case in which principal constituent elements of the circuit are integrated, so that part of the resistors and the capacitors may be disposed outside of the semiconductor substrate for adjustment of the circuit constants. By integrating the constant current circuit as one LSI, the circuit area can be reduced.

Still another embodiment of the present invention is an inverter. This inverter is provided with the above-described constant current circuit and a transistor connected to this constant current circuit as a load.

According to this embodiment, the transistor can be biased with an extremely small current.

Still another embodiment of the present invention is an oscillating circuit. This oscillating circuit is provided with a voltage-control quartz oscillator, a resistor disposed in parallel to the voltage-control quartz oscillator, and the above-described inverter which is disposed in parallel to the voltage-control quartz oscillator.

According to this embodiment, the consumption current of the circuit can be reduced.

Still another embodiment of the present invention is an electronic device. This electronic device is provided with the above-described oscillating circuit. According to this embodiment, the consumption current of the oscillating circuit can be reduced, and the life time of the battery can be extended.

It is to be noted that any arbitrary combination or rearrangement of the above-described structural components and so forth is effective as and encompassed by the present embodiments.

Morever, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram showing a configuration of a constant current circuit according to an embodiment;

FIG. 2 is a graph showing temperature dependency of the constant current Iref which is generated by the bias current source of FIG. 1 and the constant current Iref′ which is output from the constant current circuit;

FIG. 3 is a circuit diagram showing a configuration of an inverter using the constant current circuit of FIG. 1;

FIG. 4 is a circuit diagram showing a configuration of an oscillating circuit that is provided with the inverter of FIG. 3′ and

FIG. 5 is a circuit diagram showing a modification of the constant current circuit of FIG. 1.

### DETAILED DESCRIPTION OF THE INVENTION

Hereafter, the present invention will be described with reference to the drawings on the basis of suitable embodiments. Identical or equivalent constituent elements, members, processes shown in each of the drawings will be denoted with identical symbols, and description will not be appropriately repeated. In addition, the embodiments are not intended to limit the invention and are exemplifications, so that all the features and the combinations thereof described in the embodiments are not necessarily essential ones of the invention.

In the present specification, the state in which “the element A and the element B are connected” includes a case in which the element A and the element B are physically directly connected and a case in which the element A and the element B are indirectly connected via other elements that do not affect the electrical connection state.

The constant current circuit according to the embodiments described below can be suitably used for usage that generates minute currents of sub μA to several μA order.

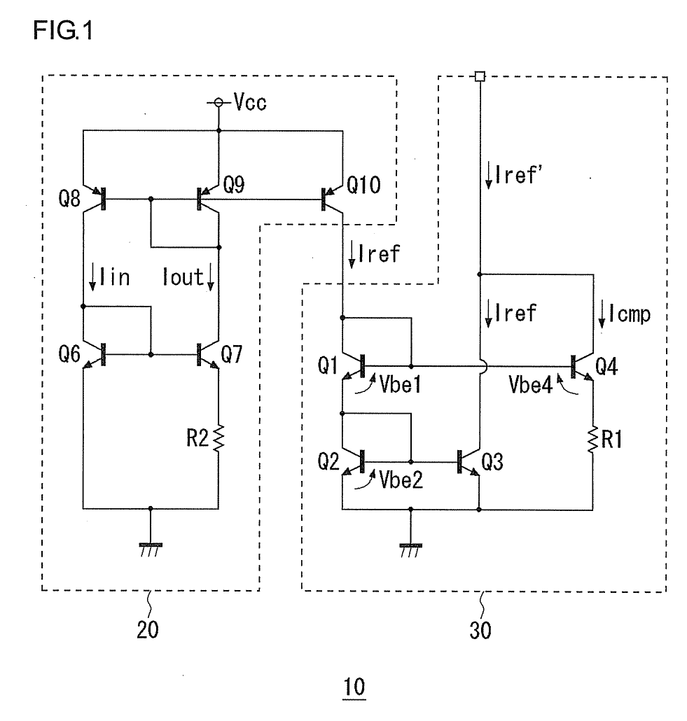

FIG. 1 is a circuit diagram showing a configuration of a constant current circuit 10 according to an embodiment. The constant current circuit 10 according to the embodiment includes a bias current source 20 and a temperature-compensating circuit 30. The bias current source 20 generates a minute constant current by using a thermal voltage Vt as a reference voltage and applying this reference voltage to a resistor. The temperature-compensating circuit 30 compensates for the temperature characteristics of the constant current Iref which is generated by the bias current source 20. This constant current circuit 10 is configured by being integrated on one semiconductor substrate.

In the following description, the symbol representing a resistor will be used also as a resistance value of the resistor. The bias current source 20 is provided with a sixth bipolar transistor Q6 and a seventh bipolar transistor Q7 of NPN type, and an eighth bipolar transistor Q8 to a tenth bipolar transistor Q10 of PNP type.

The sixth bipolar transistor Q6 has a base and a collector which are connected to each other, and has an emitter which is grounded. The seventh bipolar transistor Q7 has a base which is connected to the base of the sixth bipolar transistor Q6 and has an emitter which is connected to the ground via a current-generating resistor R2. The eighth bipolar transistor Q8 and the ninth bipolar transistor Q9 form a current mirror circuit. The eighth bipolar transistor Q8 and the ninth bipolar transistor Q9 have bases which are connected in common, and have emitters to which a power source voltage Vcc is applied. The respective collectors of the eighth bipolar transistor Q8 and the ninth bipolar transistor Q9 are connected to the collectors of the sixth bipolar transistor Q6 and the seventh bipolar transistor Q7. Namely, the eighth bipolar transistor Q8 and the ninth bipolar transistor Q9 function as a current mirror load relative to the sixth bipolar transistor Q6 and the seventh bipolar transistor Q7.

The tenth bipolar transistor Q10 is disposed in parallel to the eighth bipolar transistor Q8 and the ninth bipolar transistor Q9, and outputs a current Iref that is proportional to the current flowing through the current mirror load as a constant current. An operation of the bias current source 20 configured in this manner will be described. The saturation currents of the sixth bipolar transistor Q6 and the seventh bipolar transistor Q7 are proportional to their respective emitter areas. Now, the saturation currents of the sixth bipolar transistor Q6 and the seventh bipolar transistor Q7 are represented by Is6 and Is7, respectively, and the currents flowing through the eighth bipolar transistor Q8 and the ninth bipolar transistor Q9 are represented by Iin and Iout, respectively. The ratio Iin/Iout of the currents flowing through the eighth bipolar transistor Q8 and the ninth bipolar transistor Q9 is determined by the area ratio of the two transistors.

The voltage applied to the current-generating resistor R2 is given by the following expression (1).

Iout×R2=Vt×ln {(Iin/Iout)(Is2/Is1)} (1)

Therefore, a voltage proportional to the thermal voltage Vt is applied to the current-generating resistor R2. Also, the current Iout flowing through the current-generating resistor R2 is given by the following expression (2).

Iout=Vt×ln {(Iin/Iout)(Is2/Is1)}/R2 (2)

In this manner, the bias current source 20 generates a constant current Iout by applying to the current-generating resistor R2 a voltage proportional to the thermal voltage Vt. The constant current Iout is duplicated by the tenth bipolar transistor Q10, and is output as a constant current Iref. In the present embodiment, description will be given by assuming that the eighth bipolar transistor Q8 to the tenth bipolar transistor Q10 have the same transistor size and that Iin=Iout=Iref holds. In this case, the constant current Iref generated by the bias current source 20 is represented by the following expression (3).

Iref=Vt×α/R2 (3)

Here, α=ln {(Iin/Iout)(Is2/Is1)}.

Here, the temperature dependency of the constant current Iref generated by the bias current source 20 will be examined. The temperature dependency of the constant current Iref can be obtained by partial differentiation with each variable, and is given by the following expression (4).

$$\frac{\partial Iref}{\partial T} = \frac{Vt}{R 2} \cdot α ( \frac{1}{Vt} \frac{\partial Vt}{\partial T} - \frac{1}{R 2} \frac{\partial R 2}{\partial T} ) \qquad ( 4 )$$

Here, ∂Vt/∂T and ∂R2/∂T are each positive.

The temperature-compensating circuit 30 is disposed to cancel the temperature dependency of the constant current Iref given by the above-described expression (4). The temperature-compensating circuit 30 is provided with a first bipolar transistor Q1 to a fourth bipolar transistor Q4 and a temperature-compensating resistor R1.

The first bipolar transistor Q1 and the second bipolar transistor Q2 are disposed in series on a path of the constant current Iref generated by the bias current source 20. The first bipolar transistor Q1 and the second bipolar transistor Q2 each has a base and a collector which are connected with each other, and the second bipolar transistor Q2 has an emitter which is grounded. The first bipolar transistor Q1 and the second bipolar transistor Q2 each function as a diode.

The third bipolar transistor Q3 has a base which is connected in common to the base of the second bipolar transistor Q2, and forms a current mirror circuit. In the present embodiment, description will be given by assuming that the first bipolar transistor Q1 to the fourth bipolar transistor Q4 all have the same transistor size. In this case, the collector current of the third bipolar transistor Q3 will be equal to the collector current of the second bipolar transistor Q2, namely, the constant current Iref.

The fourth bipolar transistor Q4 has a base which is connected to the base of the first bipolar transistor Q1 and has a collector which is connected to the collector of the third bipolar transistor Q3. A temperature-compensating resistor R1 is connected between the emitter of the fourth bipolar transistor Q4 and the ground. The voltage applied to this temperature-compensating resistor R1 is given by Vbe1+Vbe2−Vbe4. Assuming that the voltages Vbe1 to Vbe4 between the base and the emitter of each transistor are all equal to each other, the voltage of Vbe will be applied to the temperature-compensating resistor R1. As a result of this, a compensating current given by Icmp=Vbe/R1 will flow through the temperature-compensating resistor R1. This compensating current Icmp is equal to the collector current of the fourth bipolar transistor Q4.

Here, the temperature dependency of the compensating current Icmp will be studied. The temperature dependency of the compensating current Icmp can be obtained by partial differentiation of the voltage Vbe between the base and the emitter of the bipolar transistor and the resistance respectively with the temperature T, and is given by the following expression (5).

$$\frac{\partial Icmp}{\partial T} = \frac{Vbe}{R 1} ( \frac{1}{Vbe} \frac{\partial Vbe}{\partial T} - \frac{1}{R 1} \frac{\partial R 1}{\partial T} ) \qquad ( 5 )$$

The temperature-compensating circuit 30 outputs a sum (Iref+Icmp) of the collector currents of the third bipolar transistor Q3 and the fourth bipolar transistor Q4 as a constant current Iref′. The temperature dependency of the constant current Iref′ which is output from the temperature-compensating circuit 30 is given by a sum of the temperature characteristics of the constant current Iref given by the expression (4) and the temperature characteristics of the compensating current Icmp given by the expression (5). Now, assuming that the temperature-compensating resistor R1 and the current-generating resistor R2 are formed from polysilicon, the temperature dependencies thereof ∂R1/∂T, ∂R2/∂T are smaller as compared with the other terms and hence can be ignored. As a result of this, the following expression (6) is obtained as temperature characteristics of the constant current Iref′ which is output from the temperature-compensating circuit 30.

$$\frac{\partial {Iref}^{′}}{\partial T} = \frac{α}{R 2} \frac{\partial Vt}{\partial T} + \frac{1}{R 1} \frac{\partial Vbe}{\partial T} \qquad ( 6 )$$

In order to restrain the temperature dependency of the constant current Iref′ which is output from the constant current circuit 10, it is sufficient that the above-mentioned expression (6) is designed to be zero. Here, ∂Vt/∂T=k/q (k: Boltzmann constant, q: electron quantum), and ∂Vbe/∂T=−2 mV/° C. holds. Therefore, since the second term on the right side of the expression (6) assumes a negative value while the first term on the right side of the expression (6) is positive, the respective terms on the right side of the expression (6) can be equated by suitably selecting the constant α, R1, and R2. For the constant α and resistance values R1, R2, optimal values may be selected by conducting a simulation or an experiment.

In this manner, with use of the constant current circuit 10 according to the present embodiment, the temperature characteristics of the constant current Iref generated by the bias current source 20 can be cancelled with the temperature characteristics of the compensating current Icmp generated by the temperature-compensating circuit 30, whereby a constant current Iref′ having small temperature dependency can be generated.

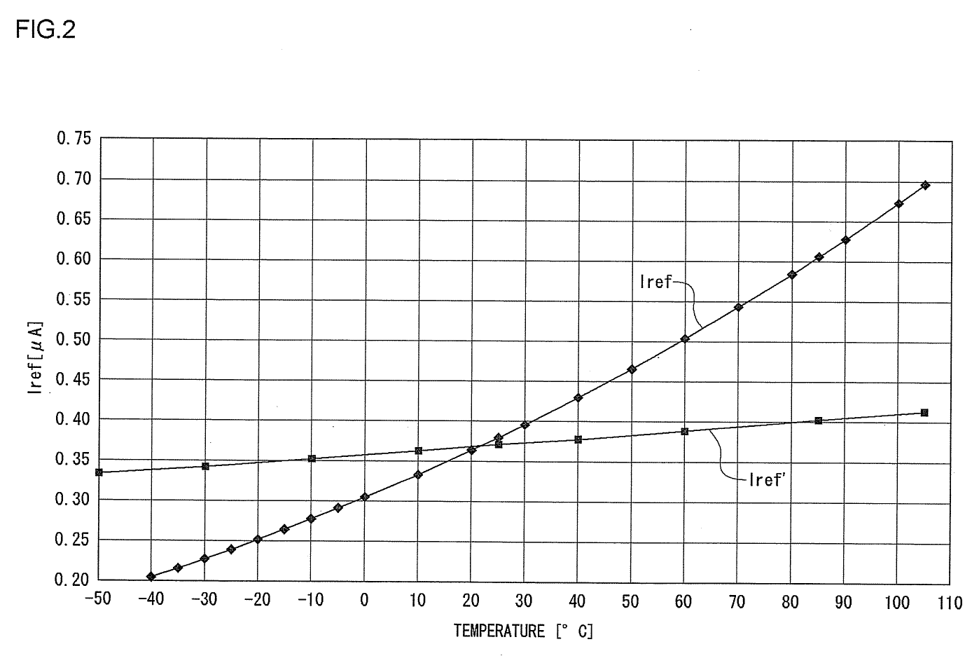

FIG. 2 is a graph showing temperature dependency of the constant current Iref which is generated by the bias current source 20 of FIG. 1 and the constant current Iref′ which is output from the constant current circuit 10. Here, the temperature dependency of FIG. 2 is an actually measured value obtained by actually fabricating the constant current circuit 10 shown in FIG. 1 and measuring the temperature dependency thereof. As shown in FIG. 2, the constant current Iref′ generated by the constant-current source 10 according to the present embodiment fluctuates only within a range of about ±10% while the constant current Iref generated by the bias current source 20 fluctuates within a range of ± several ten % within a range of −30° C. to 80° C. assuming that the ordinary temperature of 30° C. is a central value, thereby showing an improvement in the temperature characteristics.

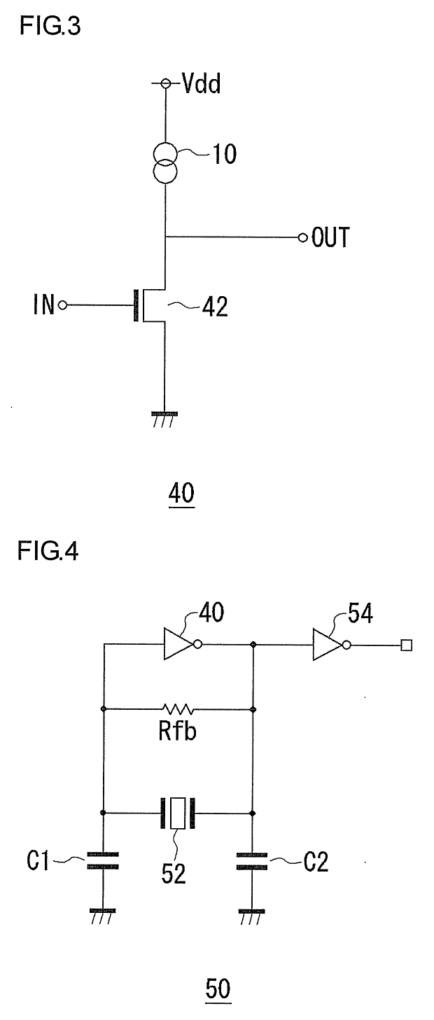

The constant current circuit 10 of FIG. 1 can be applied as a bias circuit that supplies a bias current to various circuits. FIG. 3 is a circuit diagram showing a configuration of an inverter 40 using the constant current circuit 10 of FIG. 1. The inverter 40 is provided with a transistor 42 and a constant current circuit 10. The transistor 42 is an N-channel MOSFET having a source which is grounded and having a gate to which an input signal is input. The constant current circuit 10 of FIG. 1 is connected to the drain of the transistor 42 as a constant-current load. In the inverter 40 of FIG. 3, the constant current Iref′ generated by the constant current circuit 10 is assumed to be, for example, 0.3 μA.

According to the inverter 40 configured in this manner, the operation current can be reduced to be extremely small because the circuit is biased with an extremely small constant current. Furthermore, since the temperature dependency of the constant current Iref′ generated by the constant current circuit 10 is small, good characteristics can be maintained as an inverter even if the temperature fluctuates.

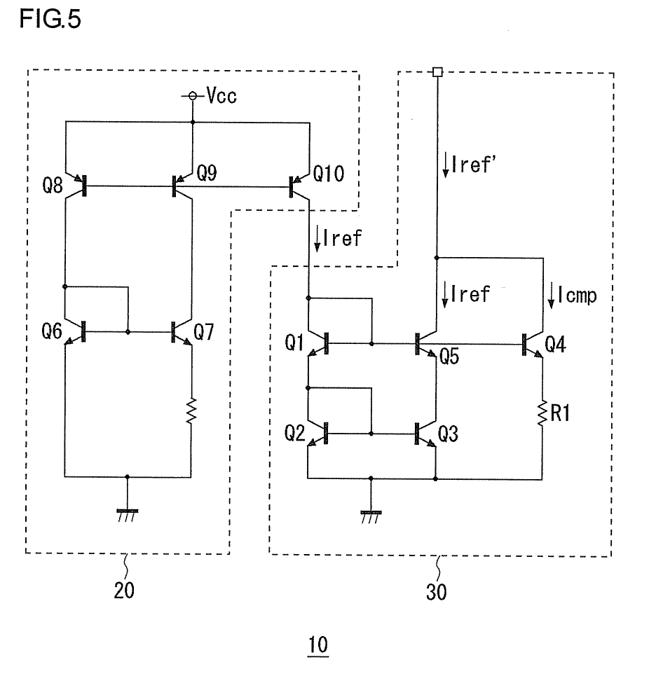

FIG. 4 is a circuit diagram showing a configuration of an oscillating circuit 50 that is provided with the inverter 40 of FIG. 3. The oscillating circuit 50 is provided with a voltage-control quartz oscillator 52, a first capacitor C1, a second capacitor C2, a feedback resistor Rfb, an inverter 40, and an inverter 54.

The both ends of the voltage-control quartz oscillator 52 are grounded via the first capacitor C1 and the second capacitor C2, respectively. The inverter 40 and the feedback resistor Rfb areconnectedinparallel to thevoltage-control quartzoscillator 52. The inverter 54 inverts the output signal of the inverter 40 for output.

Some voltage-control quartz oscillators 52 stop oscillating when the bias current of the inverter 40 decreases. Therefore, in a case in which a bias current is supplied to the transistor 42 by the bias current source 20 that is not provided with the temperature-compensating circuit 30, there is a need to maintain the set value of the bias current at ordinary temperature to be high so that a sufficient bias current may be obtained even at a low temperature. As a result, there arises a problem of increase in the consumption current of the circuit.

In contrast to this, with use of the above-described oscillating circuit 50 of FIG. 4 according to the present embodiment, a bias current with small temperature dependency of the inverter 40 can be stably generated. As a result of this, the set value of the bias current at ordinary temperature can be set to be low, whereby the circuit current can be reduced, and oscillation can be made stably within a wide temperature range.

When the oscillating circuit 50 shown in FIG. 4 is mounted, for example, on a battery-driven electronic device such as a watch, the life time of the battery can be extended by reducing the circuit current. Furthermore, as shown in FIG. 1, since the number of elements in the constant current circuit 10 is small, the circuit scale can be reduced, thereby also contributing to the scale reduction of the device.

The above-described embodiments are only exemplifications, so that it will be understood by those skilled in the art that various modifications can be made in a combination of the respective constituent elements and respective treating processes thereof, and that those modifications are also within the scope of the present invention.

FIG. 5 is a circuit diagram showing a modification of the constant current circuit 10 of FIG. 1. The constant current circuit 10 of FIG. 5 is provided with a fifth bipolar transistor Q5 in addition to the constant current circuit 10 of FIG. 1. In FIG. 5, constituent elements identical to those in FIG. 1 will be denoted with identical symbols, and duplicated description will not be repeated.

The fifth bipolar transistor Q5 of NPN type has a base connected to the base of the first bipolar transistor Q1 and has an emitter connected to the collector of the third bipolar transistor Q3. Namely, the first bipolar transistor Q1, the fifth bipolar transistor Q5, the second bipolar transistor Q2, and the third bipolar transistor Q3 are a current mirror circuit which is connected in cascade, and the collector current Iref of the fifth bipolar transistor Q5 will be a current equal to the constant current Iref which is output from the bias current source 20. The constant current circuit 10 of FIG. 5 outputs a sum of the constant current Iref which is a collector current of the fifth bipolar transistor Q5 and the compensating current Icmp which is the collector current of the fourth bipolar transistor Q4. According to the constant current circuit 10 of FIG. 5, a constant current Iref′ having small temperature dependency can be generated in a manner similar to that of the constant current circuit 10 of FIG. 1.

Also, in FIG. 1 and FIG. 5, the eighth bipolar transistor Q8 to the tenth bipolar transistor Q10 disposed in the bias current source 20 may be configured with P-channel MOSFETs. Also, the constant current may be output by setting the tenth bipolar transistor Q10 to be of NPN type and establishing a current mirror connection with the sixth bipolar transistor Q6 and the seventh bipolar transistor Q7.

The temperature-compensating circuit 30 also is not limited to the configuration of FIG. 5. For example, temperature compensation can be made with a circuit obtained by mutually substituting NPN type and PNP type and substituting the ground for the power source and the power source for the ground.

While the preferred embodiments of the present invention have been described using specific terms, such description is for illustrative purposes only, and it is to be understood that changes and variations may be made without departing from the spirit or scope of the appended claims.

1. A constant current circuit comprising:
a bias current source which generates a constant current by applying to a current-generating resistor a voltage proportional to a thermal voltage; and
a temperature-compensating circuit which generates a temperature-compensating current by applying to a temperature-compensating resistor a voltage corresponding to a voltage between a base and an emitter of a bipolar transistor, wherein
the constant current circuit outputs a sum of the constant current generated by said bias current source and the temperature-compensating current generated by said temperature-compensating circuit.

2. The constant current circuit according to claim 1, wherein
said temperature-compensating circuit comprises:
a first bipolar transistor and a second bipolar transistor which are disposed in series on a path of the constant current generated by said bias current source and whose base and collector are connected to each other;
a third bipolar transistor which forms a current mirror circuit with said second bipolar transistor; and
a fourth bipolar transistor having a base connected to the base of said first bipolar transistor, having a collector connected to the collector of said third bipolar transistor, and having an emitter connected to the temperature-compensating resistor, and
the constant current circuit outputs a sum of the collector currents of said third bipolar transistor and said fourth bipolar transistor.

3. The constant current circuit according to claim 1, wherein
said temperature-compensating circuit comprises:
a first bipolar transistor and a second bipolar transistor which are disposed in series on a path of the constant current generated by said bias current source and whose base and collector are connected to each other;
a third bipolar transistor which forms a current mirror circuit with said second bipolar transistor;
a fourth bipolar transistor having a base connected to the base of said first bipolar transistor and having an emitter connected to the temperature-compensating resistor; and
a fifth bipolar transistor having a base connected to the base of said first bipolar transistor and having an emitter connected to the collector of said third bipolar transistor, and
the constant current circuit outputs a sum of the collector currents of said fifth bipolar transistor and said fourth bipolar transistor.

4. The constant current circuit according to claim 1, wherein
said bias current source comprises:
a sixth bipolar transistor whose base and collector are connected to each other;
a seventh bipolar transistor having a base connected to the base of said sixth bipolar transistor and having an emitter connected to a fixed potential via a current-generating resistor; and
a current mirror load connected to the collectors of said sixth and seventh bipolar transistors, and
said constant current circuit outputs a current proportional to a current flowing through said current mirror load.

5. The constant current circuit according to claim 1, wherein
the constant current circuit is integrated on one semiconductor substrate.

6. An inverter, comprising:
the constant current circuit according to claims 1; and
a transistor connected to said constant current circuit as a load.

7. An oscillating circuit comprising:
a voltage-control quartz oscillator;
a feedback resistor disposed in parallel to said voltage-control quartz oscillator; and
the inverter according to claim 6 which is disposed in parallel to said voltage-control quartz oscillator.

8. An electronic device comprising the oscillating circuit according to claim 7.
